(19) United States
(12) Patent Application Publication
(10) Pub. No.: US 2009/0321712 A1
(43) Pub. Date: Dec. 31, 2009

(54) PLASMONIC COUPLING DEVICES

(75) Inventors: Robert J. Pollard, Bangor (GB); William Hendren, Carrickfergus (GB); Paul Evans, Belfast (GB); Anatoly Zayats, Belfast (GB); Gregory Wurtz, Montgomery, IL (US)

Correspondence Address: FOLEY AND LARDNER LLP;SUITE 500, 3000 K STREET NW, WASHINGTON, DC, 20007, US

(73) Assignee: The QUEEN'S UNIVERSITY OF BELFAST

(21) Appl. No.: 12/304,463

(22) PCT Filed: Jun. 12, 2007
(86) PCT No.: PCT/GB07/02168

§ 371 Date: Apr. 16, 2009

(30) Foreign Application Priority Data
Jun. 12, 2006 (GB) 0611560.4

(51) Int. Cl. H01L 29/06; B32B 7/00; C25D 5/00; B44C 1/22; G02B 6/10; H01S 5/00

(52) U.S. Cl. 257/9; 428/120; 205/112; 216/56; 385/129; 372/43.01; 257/E29.005; 977/773; 977/932

(57) ABSTRACT

A plasmonic coupling device (1) comprising a first structure (2), and a second structure (3) comprising two or more conductive nanoparticles (7), wherein each nanoparticle is elongate and is attached to the first structure such that it is oriented with a major axis thereof substantially perpendicular to the first structure. In a plasmonic coupling device comprising such nanoparticles, radiation incident on the device can produce localised surface plasmons in the nanoparticles. The localised surface plasmons can become deiocalised along the device, due to the near-field electromagnetic interaction between the two or more nanoparticles or between the one or more nanoparticles of an assembly and a nearby assembly or assemblies. This interaction allows for electro-magnetic energy, and the radiation, to be efficiently coupled between the nanoparticles or between the assemblies of one or more nanoparticles.

The invention relates to improvements relating to plasmonic coupling devices.

Plasmonic devices, such as waveguides, sensors, transistors and lasers, are widely used in a variety of applications. It is often desired to integrate such components together. Highly integrated plasmonic devices, which enable guidance and manipulation of radiation at the nanoscale level, require structural elements smaller than the wavelength of the radiation, which are designed with a nanometre-scale resolution. One approach to the design of such devices, is to construct a device using nanoscale particles, or nanoparticles, and use localised surface plasmons (LSP) for the propagation of radiation in the device. LSPs correspond to Mie resonances, which can be excited by illuminating the nanoparticles with radiation at a wavelength determined by the size and shape of the nanoparticles as well as by properties of the material of the nanoparticles. In a plasmonic device comprising such nanoparticles, the localised surface plasmons become delocalised along the device, due to the near-field electromagnetic interaction between the nanoparticles. This interaction allows for electromagnetic energy to be efficiently exchanged between the nanoparticles in the device, and thus for example for radiation to propagate from one end of the device to the other. Propagation can be achieved without suffering major bending losses.

The use of such nanoparticle plasmonic devices opens up new and unique opportunities. In nanoparticle plasmonic devices, the near-field interactions operate at short distances only (typically between a few and a few tens of nanometres), and are therefore not sensitive to abrupt directional changes that can take place within a device, when high density device integration is sought. Recently, efforts have been concentrated on implementing device architectures suited to sustain nanoscale manipulation of radiation due to near-field interactions. However, such devices often exhibit poor near-field coupling efficiencies between nanoparticles, leading to low radiation transmittance. The processing techniques of such devices have also proved to be expensive, and these have limited the applicability and wide use of this technology. Improvements in the design of nanoparticle plasmonic devices are therefore being sought.

According to a first aspect of the invention there is provided a plasmonic coupling device comprising
a first structure, and
a second structure comprising two or more conductive nanoparticles, wherein each nanoparticle is elongate and is attached to the first structure such that it is oriented with a major axis thereof substantially perpendicular to the first structure.

In a plasmonic coupling device comprising such nanoparticles, radiation incident on the device can produce localised surface plasmons in the nanoparticles. The localised surface plasmons can become delocalised along the device, due to the near-field electromagnetic interaction between the two or more nanoparticles or between the one or more nanoparticles of an assembly and a nearby assembly or assemblies. This interaction allows for electromagnetic energy, and the radiation, to be efficiently coupled between the nanoparticles or between the assemblies of one or more nanoparticles.

The orientation and shape of the nanoparticles lead to the following advantages compared to present geometries. The scattering cross-section for individual nanoparticles is increased, as their elongated shape enhances their sensitivity to fields polarized along the nanoparticle major axis. The nanoparticles may thus provide efficient nanoscale electromagnetic antennas. The plasmon damping in the plasmonic device is decreased, due to orientation of the nanoparticles perpendicular to the first structure, preventing the nanoparticles from strong interaction with the first structure. The size (diameter and length) distribution of the nanoparticles is of the order of a few percent, which enables for efficient coupling between neighbouring nanoparticles. The size (diameter and length) of the nanoparticles is tunable, which enables fine tuning of the optical properties of the plasmonic device.

At least some of the nanoparticles may have a width in the region of approximately 2 nm to approximately 500 nm, for example approximately 10 nm to approximately 100 nm. At least some of the nanoparticles may have a length in the region of approximately 50 nm to approximately 2 μm, for example approximately 50 nm to approximately 500 nm.

At least some of the nanoparticles may comprise a metallic material, for example, any of silver, gold, aluminium, platinum, copper or combinations thereof.

At least some of the nanoparticles may comprise a first end which is attached to the first structure, making electrical contact with the first structure.

At least some of the nanoparticles may comprise a wire. At least some of the wires may be substantially cylindrical in shape. At least some of the wires may be substantially conical in shape. At least some of the wires may comprise a shape having two or more sides. At least some of the wires may be substantially solid. At least some of the wires may be substantially hollow.

The plasmonic coupling device may comprise one to tens of nanoparticles.

The nanoparticles of the device may have a nanoparticle to nanoparticle separation in the region of approximately 2 nm to approximately 1500 nm nm, for example approximately 20 nm to approximately 500 nm. The nanoparticle to nanoparticle separation may be periodic, at a scale of approximately 20 nm to approximately 1.5 μm. The nanoparticle to nanoparticle separation may be quasi-periodic, at a scale of approximately 20 nm to approximately 1500 nm.

The nanoparticles of the device may comprise a desired pattern of nanoparticles. The nanoparticles may comprise at least one one-dimensional pattern of nanoparticles. For example, the one-dimensional pattern of nanoparticles may comprise a chain of nanoparticles. The nanoparticles may comprise at least one two-dimensional pattern of nanoparticles. The nanoparticles may comprise at least one quasi-periodic, hexagonal, two-dimensional pattern of nanoparticles. The patterns of the nanoparticles may have a nanometre scale period. The patterns of the nanoparticles may have a micrometre scale period.

The plasmonic coupling device may comprise an electrode. The electrode may be patterned to address one or more of the nanoparticles.

The second structure may comprise two or more assemblies each comprising one or more conductive nanoparticles.

At least some of the assemblies of one or more nanoparticles may comprise one to tens of nanoparticles.

At least some of the assemblies of one or more nanoparticles may comprise a plurality of nanoparticles. At least some of the assemblies of a plurality of nanoparticles may have a nanoparticle to nanoparticle separation in the region of approximately 2 nm to approximately 1500 nm nm, for example approximately 20 nm to approximately 500 nm. The nanoparticle to nanoparticle separation may be periodic, at a scale of approximately 20 nm to approximately 1.5 μm. The nanoparticle to nanoparticle separation may be quasi-periodic, at a scale of approximately 20 nm to approximately 1500 nm.

At least some of the assemblies of a plurality of nanoparticles may comprise a desired pattern of nanoparticles. At least some of the assemblies of a plurality of nanoparticles may comprise at least one one-dimensional pattern of nanoparticles. At least some of the assemblies of a plurality of nanoparticles may comprise at least one two-dimensional pattern of nanoparticles. At least some of the assemblies of a plurality of nanoparticles may comprise at least one quasi-periodic, hexagonal, two-dimensional pattern of nanoparticles. The patterns of the nanoparticles may have a nanometre scale period. The patterns of the nanoparticles may have a micrometre scale period.

The plasmonic coupling device may comprise a plurality of assemblies of one or more nanoparticles, at least some of which assemblies have a separation in the region of approximately 50 nm to approximately 1 .5 μm. The assemblies may have a periodic separation. The assemblies may have a quasi-periodic separation.

The plasmonic coupling device may comprise a desired arrangement of assemblies of one or more nanoparticles. The plasmonic coupling device may comprise at least one periodic arrangement of assemblies of one or more nanoparticles. The plasmonic coupling device may comprise at least one one-dimensional arrangement of assemblies of one or more nanoparticles. For example, the one-dimensional arrangement of assemblies of one or more nanoparticles may comprise a chain of assemblies of one or more nanoparticles, which may have a period in the region of approximately 50 nm to approximately 1 5 μm. The plasmonic coupling device may comprise at least one two-dimensional arrangement of assemblies of one or more nanoparticles.

The plasmonic coupling device may comprise an electrode. The electrode may be patterned to address one or more of the assemblies of one or more nanoparticles. The electrode may be patterned to address the or at least some of the nanoparticles in one or more of the assemblies.

The second structure of the plasmonic coupling device may comprise an insulator material. The insulator material may comprise, for example, air, or alumina, or silicon, or a polymer substance. The insulator material may separate at least some of the nanoparticles of the device. The insulator material may separate at least some of the assemblies of one or more nanoparticles. When one or more assemblies comprise a plurality of nanoparticles, the insulator material may separate at least some of nanoparticles of at least some of the assemblies.

The insulator material may contain a plurality of pores. At least some of the pores may be oriented with a major axis thereof substantially perpendicular to the first structure. At least some of the pores may have a substantially cylindrical shape. At least some of the pores may comprise a shape having one or more sides. At least some of the pores may have a width in the region of approximately 2 nm to approximately 500 nm, for example approximately 10 nm to approximately 100 nm. At least some of the pores may have a separation in the region of approximately 2 nm to approximately 1500 nm, for example approximately 20 nm to approximately 500 nm.

At least some of the nanoparticles of the device may be contained in a pore. At least some of the nanoparticles may be oriented within a pore with a major axis of the nanoparticle substantially parallel to a major axis of the pore. At least some of the nanoparticles may be contained in a pore, with a space between at least a part of the nanoparticle and at least a part of the pore. At least some of the nanoparticles may be contained in a pore, with a space between substantially all of the nanoparticle and the pore.

For at least some of the assemblies, the or each or at least some of the nanoparticles may be contained in a pore. For at least some of the assemblies, the or at least some of the nanoparticles may be oriented within a pore with a major axis of the nanoparticle substantially parallel to a major axis of the pore. For at least some of the assemblies, the or at least some of the nanoparticles may be contained in a pore, with a space between at least a part of the nanoparticle and at least a part of the pore. For at least some of the assemblies, the or at least some of the nanoparticles may be contained in a pore, with a space between substantially all of the nanoparticle and the pore.

At least some of the spaces may be at least partially filled with at least one substance. The substance can be solid, liquid or gas. The substance may be, for example, air. The substance may comprise, for example, one or more molecules. The substance may comprise, for example, one or more nanoparticles. The substance may be, for example, a bio-substance. The nanostructured system may then act as a biosensor. The substance may be, for example, a substance capable of a non linear optical response. The nanostructured system may then act as a plasmonic sensor or an plasmonic transistor. The substance may be, for example, a substance capable of stimulation. The stimulation may comprise, for example, optical stimulation. The nanostructured system may then act as a laser. The stimulation may comprise electrical stimulation, and/or magnetic stimulation.

The first structure of the plasmonic coupling device may comprise one or more layers. When the first structure comprises two or more layers, these may be attached together. The or each layer may comprise conductive material. The or each layer may comprise a metallic conductive material, for example any of gold, silver, copper, indium tin oxide, aluminium, tantalum, platinum, iridium, SrRuO₃, (La_{1/2}Sr_{1/2})CoO₃, or combinations thereof. The or each layer may act as an electrode. The first structure may have a thickness in the region of approximately 10 nm to approximately 1000 nm.

The plasmonic coupling device may further comprise a third structure. The third structure may be attached to the first structure. The third structure may act as a substrate for the plasmonic coupling device, providing a mechanical support for the device. The third structure may comprise one or more layers. The third structure may comprise silicon. The third structure may comprise a glass material.

The plasmonic coupling device may have a thickness in the region of approximately 50 nm to approximately 2000 nm.

According to a second aspect of the present invention there is provided a method of manufacturing a plasmonic coupling device, comprising the steps of:
forming a first structure, and
forming a second structure comprising two or more conductive nanoparticles, by
forming insulator material comprising two or more pores on a surface of the first structure, and
forming a nanoparticle in at least two of the pores,
wherein the or each nanoparticle is elongate and is oriented with a major axis thereof substantially perpendicular to the first structure.

According to a third aspect of the present invention there is provided a method of manufacturing a plasmonic coupling device, comprising the steps of:
forming a first structure, and
forming a second structure comprising two or more assemblies each comprising one or more conductive nanoparticles, by
forming insulator material comprising two or more assemblies each comprising one or more pores on a surface of the first structure, and forming a nanoparticle in the or at least some of the pores of the two or more assemblies,
wherein the or each nanoparticle is elongate and is oriented with a major axis thereof substantially perpendicular to the first structure.

Forming the insulator material on the surface of the first structure may comprise placing at least one layer of conductive material on the first structure, and treating the layer of conductive material to form the insulator material. Treating the layer of conductive material may comprise anodisation of the conductive material to form the insulator material.

Anodisation of the conductive material may comprise electrochemical growth of the insulator material. Anodisation of the conductive material may form a template of the insulator material.

The layer of conductive material may comprise aluminium, which may be treated by anodisation to form an insulator material comprising alumina. The alumina insulator material may have an anisotropic structure.

Treating the layer of conductive material to form the insulator material may also cause formation of the two or more assemblies of one or more pores in the insulator material. At least some of the pores may form along a growth direction of the insulator material. At least some of the pores may be oriented with a major axis thereof substantially perpendicular to the first structure.

At least some of the pores may have a substantially cylindrical shape. At least some of the pores may have a shape comprising one or two or more sides.

At least some of the pores may have a length which is controlled by controlling the thickness of the layer of conductive material. At least some of the pores may have a length in the region of a few tens of nanometres up to several microns.

At least some of the pores may have a size which is controlled by choosing conditions for the treating of the layer of conductive material. At least some of the pores may have a width in the region of approximately 2 nm to approximately 500 nm, for example approximately 10 nm to approximately 100 nm.

At least some of the pores may have a separation which is controlled by choosing conditions for the treating of the layer of conductive material. At least some of the pores may have a separation in the region of approximately 2 nm to approximately 1500 nm, for example approximately 20 nm to approximately 500 nm.

Formation of at least some of the pores in the insulator material may comprise a process to extend the or each pore to reach the first structure. This may involve a milling process, for example an argon ion milling process, or a chemical etching process.

Forming a nanoparticle in a pore of the insulator material may comprise, for example, any of an electro-deposition method, or a physical vapour deposition method or a chemical deposition method. Forming a nanoparticle in a pore of the insulator material may comprise electrochemically growing the nanoparticle in the pore. Forming a nanoparticle in a pore of the insulator material may substantially fill the pore.

At least some of the nanoparticles may have a width in the region of approximately 2 nm to approximately 500 nm, for example approximately 10 nm to approximately 100 nm. At least some of the nanoparticles may have a length in the region of approximately 50 nm to approximately 2 μm, for example approximately 50 nm to approximately 500 nm.

At least some of the nanoparticles may comprise a metallic material, for example, any of silver, gold, aluminium, platinum, copper or combinations thereof.

At least some of the nanoparticles may comprise a first end which is attached to the first structure, making electrical contact with the first structure.

At least some of the nanoparticles may comprise a wire. At least some of the wires may be substantially cylindrical in shape. At least some of the wires may be substantially conical in shape. At least some of the wires may comprise a shape having one or two or more sides. At least some of the wires may be substantially solid. At least some of the wires may be substantially hollow.

The method may comprise obtaining a desired arrangement of the assemblies of one or more nanoparticles. The desired arrangement of assemblies may be a regular arrangement of assemblies. The desired arrangement of assemblies may be a regular one-dimensional arrangement of assemblies. For example, the one-dimensional arrangement of assemblies may comprise a chain of assemblies, which may have a period in the region of approximately 50 nm to a few micrometres. The desired arrangement of assemblies may be a regular two-dimensional arrangement of assemblies. The desired arrangement of assemblies may be a irregular arrangement of assemblies. The desired arrangement of assemblies may be a irregular one-dimensional arrangement of assemblies. The desired arrangement of assemblies may be a irregular two-dimensional arrangement of assemblies.

Obtaining a desired arrangement of assemblies of one or more nanoparticles may comprise allowing the pores to form in the insulator material in a pattern which is at least partially dictated by one or more characteristics of the layer of conductive material forming the insulator material, and forming nanoparticles in appropriate pores so as to obtain the desired arrangement of assemblies of one or more nanoparticles. The pores may form in a pattern which is at least partially dictated by, for example, the surface topography and thickness of the layer of conductive material. The pattern may approximate a hexagonal pattern.

Forming nanoparticles in appropriate pores may comprise forming at least one layer on the insulator material, treating the at least one layer to expose the appropriate pores, and forming nanoparticles in the appropriate pores. Treating the at least one layer to expose the appropriate pores may comprise a lithographic process. Treating the at least one layer to expose the appropriate pores may comprise a milling process.

Forming nanoparticles in appropriate pores may comprise providing the plasmonic coupling device with an electrode which is patterned to allow growth of nanoparticles in the appropriate pores, and using this to form nanoparticles in the appropriate pores.

Obtaining a desired arrangement of assemblies of one or more nanoparticles may comprise providing the plasmonic coupling device with an electrode which is patterned to allow growth of nanoparticles, using the patterned electrode to form arrays of assemblies of nanoparticles, and using the patterned electrode to address the desired arrangement of assemblies.

Obtaining a desired arrangement of assemblies of one or more nanoparticles may comprise processing the layer of conductive material prior to treatment thereof to form the insulator material to form an arrangement of assemblies of one or more pores, and forming nanoparticles in the pores to obtain the desired arrangement of assemblies of one or more nanoparticles. The processing may comprise multi-stage anodisation of the layer of conductive material. The processing may comprise texturing the layer of conductive material. Texturing the layer of conductive material may provide nucleation sites for the formation of the pores. Texturing the layer of conductive material may comprise imprinting the layer of conductive material. Texturing the layer of conductive material may comprise a photolithographic treatment of the layer of conductive material. The photolithographic process may allow control of the periodicity of the arrangement of assemblies of one or more pores. The photolithographic treatment may allow the production of arrangements of assemblies of one or more nanoparticles, for example having an assembly-to-assembly separation in the region of approximately 100 nm to approximately 1.5 μm.

Obtaining a desired arrangement of assemblies of one or more nanoparticles may comprise processing the layer of conductive material prior to treatment thereof to form the insulator material to form an arrangement of assemblies of one or more pores, and forming nanoparticles in appropriate pores to obtain the desired arrangement of assemblies of one or more nanoparticles.

Processing the layer of conductive material may comprise multi-stage anodisation of the layer of conductive material. Processing the layer of conductive material may comprise texturing the layer of conductive material. Texturing the layer of conductive material may comprise imprinting the layer of conductive material. Texturing the layer of conductive material may comprise a photolithographic treatment of the layer of conductive material.

Forming nanoparticles in appropriate pores may comprise forming at least one layer on the insulator material, treating the at least one layer to expose the appropriate pores, and forming nanoparticles in the appropriate pores. Treating the at least one layer to expose the appropriate pores may comprise a lithographic process. Treating the at least one layer to expose the appropriate pores may comprise a milling process.

Forming nanoparticles in appropriate pores may comprise providing the plasmonic coupling device with an electrode which is patterned to allow growth of nanoparticles in the appropriate pores, and using this to form nanoparticles in the appropriate pores.

At least some of the assemblies of one or more nanoparticles may comprise a plurality of nanoparticles. The method may comprise obtaining a desired pattern of nanoparticles in at least one assembly of a plurality of nanoparticles. The desired pattern of nanoparticles may be a regular pattern of nanoparticles. The desired pattern of nanoparticles may be a regular one-dimensional pattern of nanoparticles. For example, the one-dimensional pattern of nanoparticles may comprise a chain of nanoparticles, which may have a period in the region of approximately 20 nm to 500 nm. The desired pattern of nanoparticles may be a regular two-dimensional pattern of nanoparticles. The desired pattern of nanoparticles may be an irregular pattern of nanoparticles. The desired pattern of nanoparticles may be an irregular one-dimensional pattern of nanoparticles. The desired pattern of nanoparticles may be an irregular two-dimensional pattern of nanoparticles.

Obtaining a desired pattern of nanoparticles in the at least one assembly may comprise allowing the pores to form in the insulator material in a pattern which is at least partially dictated by one or more characteristics of the layer of conductive material forming the insulator material, and forming nanoparticles in appropriate pores so as to obtain the desired pattern of nanoparticles in the at least one assembly. The pores may form in a pattern which is at least partially dictated by, for example, the surface topography and thickness of the layer of conductive material. The pattern may approximate a hexagonal pattern.

Forming nanoparticles in appropriate pores may comprise forming at least one layer on the insulator material, treating the at least one layer to expose the appropriate pores, and forming nanoparticles in the appropriate pores. Treating the at least one layer to expose the appropriate pores may comprise a lithographic process. Treating the at least one layer to expose the appropriate pores may comprise a milling process.

Forming nanoparticles in appropriate pores may comprise providing the plasmonic coupling device with an electrode which is patterned to allow growth of nanoparticles in the appropriate pores, and using this to form nanoparticles in the appropriate pores.

Obtaining a desired pattern of nanoparticles in at least one assembly may comprise processing the layer of conductive material prior to treatment thereof to form the insulator material to form a pattern of pores in at least one assembly, and forming nanoparticles in the pores to obtain the desired pattern of nanoparticles in the at least one assembly. The processing may comprise multi-stage anodisation of the layer of conductive material. The processing may comprise texturing the layer of conductive material. Texturing the layer of conductive material may provide nucleation sites for the formation of the pores. Texturing the layer of conductive material may comprise imprinting the layer of conductive material. Texturing the layer of conductive material may comprise a photolithographic treatment of the layer of conductive material. The photolithographic process may allow control of the periodicity of the pattern of nanoparticles in the at least one assembly. The photolithographic treatment may allow the production of patterns of nanoparticles in the at least one assembly, for example having an pore-to-pore separation in the region of approximately 20 nm to approximately 500 nm. The photolithographic process may allow control of the number of pores in the pattern of nanoparticles in the at least one assembly.

Obtaining a desired pattern of nanoparticles in at least one assembly may comprise processing the layer of conductive material prior to treatment thereof to form the insulator material to form a pattern of pores in at least one assembly, and forming nanoparticles in appropriate pores to obtain the desired pattern of nanoparticles in the at least one assembly.

Processing the layer of conductive material may comprise multi-stage anodisation of the layer of conductive material. Processing the layer of conductive material may comprise texturing the layer of conductive material. Texturing the layer of conductive material may comprise imprinting the layer of conductive material. Texturing the layer of conductive material may comprise a photolithographic treatment of the layer of conductive material.

Forming nanoparticles in appropriate pores may comprise forming at least one layer on the insulator material, treating the at least one layer to expose the appropriate pores, and forming nanoparticles in the appropriate pores. Treating the at least one layer to expose the appropriate pores may comprise a lithographic process. Treating the at least one layer to expose the appropriate pores may comprise a milling process.

Forming nanoparticles in appropriate pores may comprise providing the plasmonic coupling device with an electrode which is patterned to allow growth of nanoparticles in the appropriate pores, and using this to form nanoparticles in the appropriate pores.

The method may comprise removing at least some of the insulator material from the plasmonic coupling device after formation of the nanoparticles. Removing at least some of the insulator material from the device may comprise chemically removing the material.

Alternatively, the insulator material may be maintained in the plasmonic coupling device. The insulator material may separate at least some of the assemblies of one or more nanoparticles. When one or more assemblies comprise a plurality of nanoparticles, the insulator material may separate at least some of nanoparticles of at least some of the assemblies.

The insulator material of at least some of the pores containing a nanoparticle may abut substantially all of the nanoparticle. The insulator material of at least some of the pores containing a nanoparticle may be spaced from at least a part of the nanoparticle. The insulator material of at least some of the pores containing a nanoparticle may be spaced from substantially all of the nanoparticle. The method may comprise removing material from at least some of the pores containing a nanoparticle to provide a space between the insulator material and the nanoparticle. Removing material from at least some of the pores containing a nanoparticle may comprise etching insulator material surrounding a pore. Etching the insulator material surrounding a pore may comprise channelling an etching substance along the nanoparticle contained in the pore and etching outwards from the nanoparticle.

At least some of the spaces may be at least partially filled with at least one substance. The substance can be solid, liquid or gas. The substance may be, for example, air. The substance may comprise, for example, one or more molecules. The substance may comprise, for example, one or more nanoparticles. The substance may be, for example, a bio-substance. The nanostructured system may then act as a biosensor. The substance may be, for example, a substance capable of a non linear optical response. The nanostructured system may then act as a photonic sensor or an optical transistor. The substance may be, for example, a substance capable of stimulation. The stimulation may comprise, for example, optical stimulation. The nanostructured system may then act as a laser. The stimulation may comprise electrical stimulation, and/or magnetic stimulation.

The first structure may be formed on a substrate structure. The first structure may be formed on the substrate structure by a deposition method, for example, a sputtering deposition method, or a PLD method, or an electrodeposition method, or an evaporation method, or a chemical method. The substrate may comprise a dielectric material.

The method of manufacturing the plasmonic coupling device allows for fast, easy and large-scale fabrication of the device. This provides an industry-suitable manufacturing method.

The plasmonic coupling device of the first and second aspects of the invention may be incorporated in a number of instruments. The development of these instruments is motivated by the fact that the nonlinear properties required for controlling radiation, are greatly enhanced in nanostructure plasmonic instruments, due to the electromagnetic field confinement effects associated with the sub-wavelength size of the nanoparticles in the instruments and electromagnetic resonances of the plasmonic modes of the nanoparticle system. These effects decrease the power needed to operate such instruments, and these instruments can operate at ultra low radiation intensities. Such plasmonic instruments may provide a new generation of active nanoplasmonic instruments. Due to their nanoscale size, a plurality of the plasmonic instruments may be integrated into one nanoscale architecture.

According to a fourth aspect of the invention there is provided a waveguide comprising one or more plasmonic coupling devices according to the first aspect of the invention.

The waveguide will use coupling between localised surface plasmons for the propagation of radiation therein. The localised surface plasmons sustained by individual assemblies of one or more nanoparticles, become delocalised along the waveguide, due to near-field electromagnetic interactions between the assemblies of one or more nanoparticles. These interactions allow for electromagnetic energy to be efficiently coupled between the assemblies in the waveguide, and thus for radiation to propagate from one end of the waveguide to the other. The near-field interactions operate at short distances only (typically between a few and a few tens of nanometres), and are therefore not sensitive to abrupt directional changes that can take place within a waveguide, when high density device integration is sought. The waveguide may be a wavelength selective waveguide.

At least some of the plasmonic coupling devices of the waveguide may comprise an insulator material. The insulator material may separate at least some of the assemblies of one or more nanoparticles, and/or at least some nanoparticles in at least some assemblies of a plurality of nanoparticles. The insulator material may contain a plurality of pores, at least some of which may contain a nanoparticle. For at least some of the pores containing a nanoparticle, the pore may contain a space between at least a part of the nanoparticle and at least a part of the pore. At least some of the spaces may be at least partially filled with at least one substance. The substance can be solid, liquid or gas. The substance may be, for example, air. The substance may comprise, for example, one or more molecules. The substance may comprise, for example, one or more nanoparticles. The substance may be, for example, a bio-substance. The nanostructured system may then act as a biosensor. The substance may be, for example, a substance capable of a non linear optical response. The nanostructured system may then act as a photonic sensor or an optical transistor. The substance may be, for example, a substance capable of stimulation. The stimulation may comprise, for example, optical stimulation. The nanostructured system may then act as a laser. The stimulation may comprise electrical stimulation, and/or magnetic stimulation.

The throughput spectrum of the waveguide may be controllable. This may be achieved by tuning one or more properties of at least some of the nanoparticles. This may be achieved by tuning the diameter of at least some of the nanoparticles, during fabrication of the waveguide. This may be achieved by tuning the length of at least some of the nanoparticles, during fabrication of the waveguide. This may be achieved by tuning the distance between at least some of the nanoparticles, or assemblies of nanoparticles during fabrication of the waveguide. This may be achieved by tuning the dielectric constant of the insulator material, when provided, during fabrication of the waveguide. This may be achieved by tuning the dielectric constant of the material in at least some of the spaces when provided.

According to a fifth aspect of the invention there is provided a plasmonic sensor comprising one or more plasmonic coupling devices according to the first aspect of the invention.

At least some of the plasmonic coupling devices of the plasmonic sensor may comprise an insulator material. The insulator material may contain a plurality of pores, at least some of which may contain a nanoparticle. For at least some of the pores containing a nanoparticle, the pore may contain a space between at least a part of the nanoparticle and at least a part of the pore. For at least some of the pores containing a nanoparticle, the pore may contain a space between substantially all of the nanoparticle and the pore. At least some of the spaces may be at least partially filled with at least one substance. The substance can be solid, liquid or gas. The substance may be, for example, air. The substance may comprise, for example, one or more molecules. The substance may comprise, for example, one or more nanoparticles. The substance may be, for example, a bio-substance. The nanostructured system may then act as a biosensor. The substance may be, for example, a substance capable of a non linear optical response. The nanostructured system may then act as a photonic sensor or an optical transistor. The substance may be, for example, a substance capable of stimulation. The stimulation may comprise, for example, optical stimulation. The nanostructured system may then act as a laser. The stimulation may comprise electrical stimulation, and/or magnetic stimulation.

According to a sixth aspect of the invention there is provided a transistor comprising one or more plasmonic coupling devices according to the first aspect of the invention.

At least some of the plasmonic coupling devices of the transistor may comprise a dielectric insulator material. The dielectric insulator material may comprise an active plasmonic material capable of exhibiting a nonlinear response to excitation.

The transistor may operate by using near-field interactions of the assemblies of one or more nanoparticles of at least some of the plasmonic coupling devices, to excite the dielectric insulator material, to produce a nonlinear response which modulates transmittance of the or each device. This allows the or each device to act as a transistor. The transmittance of the or each device may be modulated by altering the spectral sensitivity of the device or its transmission (guiding properties). The latter can be achieved via mechanical alteration of the separation between the assemblies of one or more nanoparticles, using, for example, piezo-electric materials and applied voltage.

The dielectric insulator material may exhibit a nonlinear response to excitation affecting the refractive index of the material. The refractive index of the material may be controlled by illumination with a signal. This allows control of the transmittance of the transistor. The dielectric insulator material may comprise a non-linear polymer, such as poly-3-butoxy-carbonyl-methyl-urethane (3BCMU), or 4BCMU or BM4i4i dye.

According to a seventh aspect of the invention there is provided a laser comprising one or more plasmonic coupling devices according to the first aspect of the invention.

At least some of the plasmonic coupling devices of the laser may comprise an insulator material. The insulator material may comprise a material capable of optical gain/optical stimulation. The laser may operate by using the plasmonic modes excited in the interacting assemblies of one or more nanoparticles of at least some of the plasmonic coupling devices, to stimulate the insulator material of the devices and generate stimulated emission from the or each device. The or each device thus acts as a laser. The strong spatial localisation of the surface plasmons leads to locally enhanced electromagnetic field intensities, and allow generation of a low-power laser.

The material capable of stimulation may comprise an organic dye, such as 1,1′-diethyl-3,3′-bis(4-sulfobutyl)-5,5′,6,6′-tetrachlorobenzimidazolocarbocyanine (TDBC).

At least some of the plasmonic coupling devices of the laser may comprise hollow nanoparticles. At least some of the hollow nanoparticles may be at least partially filled with at least one substance. The substance may be a substance which is capable of optical stimulation. The or each or some of the hollow nanoparticles may then provide a lasing cavity. The or each or some of the lasing cavities may be spectrally tuned by providing a substance in a space between a hollow nanoparticle and a pore of insulator material containing the nanoparticle.

An embodiment of the invention will now be described, by way of example only, with reference to the accompanying drawings, in which

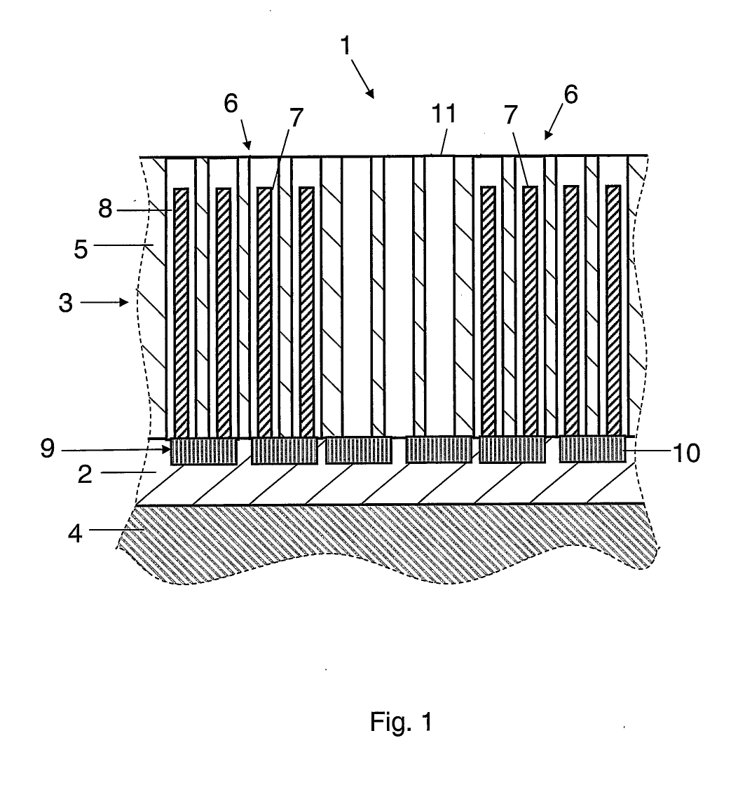

FIG. 1 is a schematic cross sectional representation of a plasmonic coupling device according to the first aspect of the invention, and

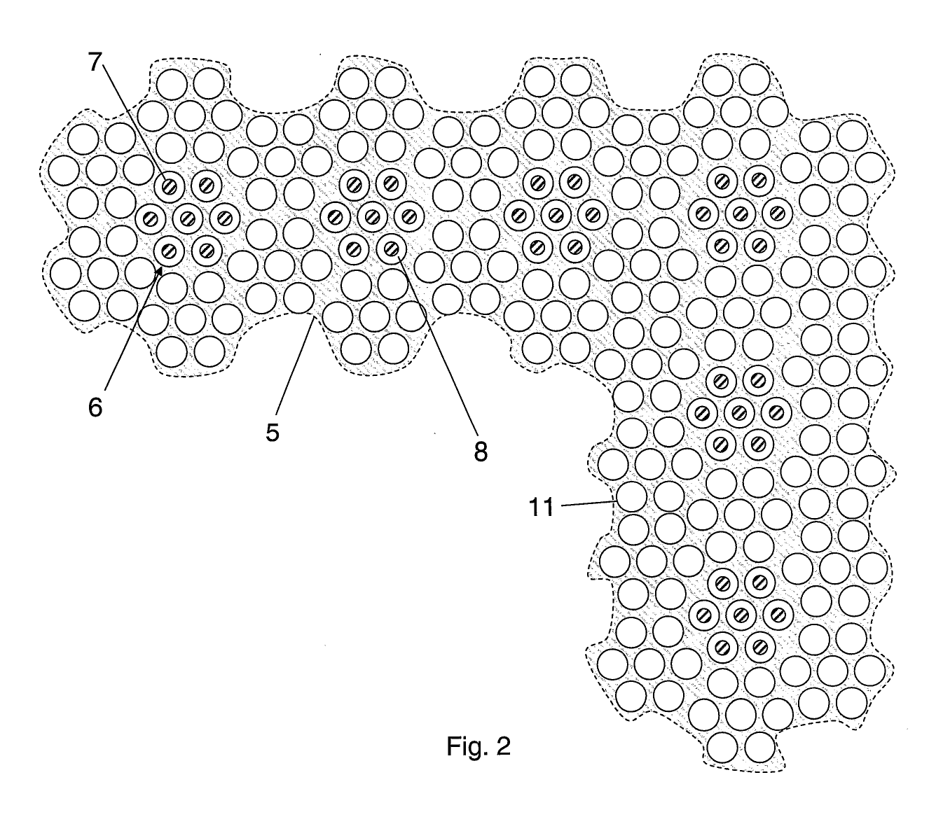

FIG. 2 is a schematic plan representation of the plasmonic coupling device of FIG. 1.

FIGS. 1 and 2 show a plasmonic coupling device 1, comprising a first structure 2, a second structure 3, and a substrate 4.

The first structure 2 is formed from a least one layer of material. One layer of the first structure 2 comprises a patterned electrode 9 comprising gold. The patterned electrode 9 consists of electrically isolated and individually electrically addressable regions 10. For example, regions 10 may be approximately 2500 nm². The patterned electrode 9 may be fabricated by lithography.

The first structure 2 is formed on a substrate 4, by a deposition process. The substrate 4 provides a mechanical support for the first and second structures. The substrate 4 may comprise, for example, a semiconductor, or insulator, or dielectric, or metallic material.

The second structure 3 comprises insulator material 5 and two assemblies 6 of conductive nanoparticles 7. Each assembly 6 comprises a plurality of nanoparticles 7. Each plurality of nanoparticles 7 acts as one effective nanoparticle, with highly tunable spectral properties. The nanoparticles 7 are formed from gold. The nanoparticles 7 are elongate in shape, and are oriented with their major axis substantially perpendicular to the first structure 2. Each nanoparticle 7 is substantially cylindrical in shape, although it will be appreciated that other shapes may be provided, and forms a nanowire. Each nanoparticle 7 has a width of approximately 20 nm, and a length of approximately 500 nm. Each nanoparticle 7 may be solid or may be hollow. Each nanoparticle 7 comprises a first end which extends to and abuts the first structure 2, and forms an electrical contact with the conductive gold of this structure.

The insulator material 5 is formed from alumina. The insulator material separates the assemblies 6 of nanoparticles 7, and separates the nanoparticles 7 in each assembly 6. The insulator material 5 contains a plurality of pores 11. Some of the pores contain a nanoparticle 7 and a space 8 between the nanoparticle and the pore. A space 8 is provided between substantially all of a nanoparticle and the pore containing it.

The second structure 3 is formed on a surface of the first structure 2 by firstly depositing a layer of aluminium on the surface of the first structure 2. The aluminium layer is then treated by anodisation, to form alumina insulator material. This comprises electrochemical growth of the alumina insulator material.

The anodisation process also causes formation of a plurality of pores 11 in the alumina insulator material 5. The pores form along a growth direction of the alumina insulator material, and are oriented with a major axis thereof substantially perpendicular to the first structure 2. The pores are substantially cylindrical in shape. The length of the pores is controlled by the thickness of the layer of aluminium deposited on the surface of the first structure 2. The diameter of the pores is controlled by choosing conditions for the anodisation of the aluminium layer.

A desired arrangement of the assemblies 6 of the nanoparticles 7 is obtained, by allowing the pores 11 to form in the insulator material 5 in a pattern which is at least partially dictated by one or more characteristics of the layer of conductive material forming the insulator material, and forming nanoparticles 7 in appropriate pores 11 so as to obtain the desired arrangement of assemblies of one or more nanoparticles. The pores 11 form in a pattern which is at least partially dictated by the surface topography and thickness of the layer of conductive material, which pattern is approximately a hexagonal pattern.

Forming the nanoparticles 7 in appropriate pores comprises using the patterned electrode 9, and applying a bias to only some of the regions 10 of the patterned electrode 9. The nanoparticles 7 are electrochemically grown in the pores 11, by applying a bias to some of the regions 10 of the patterned electrode 9. This determines the geometrical arrangement of the assemblies 6. This arrangement may be one dimensional, and may be periodic having a periodicity of, for example, 400 nm.

The bias applied to the regions 10 of the patterned electrode 9 is controlled, to determine the size and shape of the nanoparticles 7 in each assembly 6. For example, the controlled bias applied to the regions 10 of the patterned electrode 9 determines the length of the nanoparticles 7 grown in the assemblies 6. Adjacent assemblies of nanoparticles may have different lengths. For example, the controlled bias applied to the regions 10 of the patterned electrode 9 determines the material of the nanoparticles 7 grown in the assemblies 6. Adjacent assemblies of nanoparticles may comprise different materials, for example gold and silver.

The patterned electrode 9 hence allows enhanced control over the fabrication of plasmonic coupling devices with chosen plasmonic properties.

Alternatively, forming the nanoparticles 7 in appropriate pores comprises forming at least one layer on the a ‘free’ surface of the insulator material 5, and treating the at least one layer, using lithographic processes, to expose the appropriate pores, and forming nanoparticles in the appropriate pores.

A nanoparticle 7 is formed in the appropriate pores of the alumina insulator material 5, by, for example, an electro-deposition method, or a physical vapour deposition method or a chemical deposition method. A nanoparticle will be electrochemically grown in the pore. A nanoparticle is oriented within a pore with its major axis substantially parallel to a major axis of the pore, i.e. the nanoparticle is oriented with its major axis substantially perpendicular to the first structure 2.

The alumina insulator material 5 of the plasmonic coupling device 1 may be chemically removed from the device after formation of the nanoparticles.

Alternatively, at least some of the insulator material 5 may be maintained in the device. The insulator material may separate the assemblies 6 of nanoparticles 7 of the device, and the nanoparticles 7 in each assembly 6.

Alumina insulator material 5 may be removed from at least some of the pores 11 containing a nanoparticle to provide a space 8 between the alumina insulator material 5 and the nanoparticle 7. This may comprise etching insulator material surrounding a pore 11, by channelling an etching substance along the nanoparticle 7 contained in the pore 11 and etching outwards from the nanoparticle 7.

The spaces 8 may be at least partially filled with at least one substance. The substance can be solid, liquid or gas. The substance may be, for example, air. The substance may comprise, for example, one or more molecules. The substance may comprise, for example, one or more nanoparticles. The substance may be, for example, a bio-substance. The nanostructured system may then act as a biosensor. The substance may be, for example, a substance capable of a non linear optical response. The nanostructured system may then act as a photonic sensor or an optical transistor. The substance may be, for example, a substance capable of stimulation. The stimulation may comprise, for example, optical stimulation. The nanostructured system may then act as a laser. The stimulation may comprise electrical stimulation, and/or magnetic stimulation.

The plasmonic/photonic properties of the plasmonic coupling device 1 may be dynamically controlled through the addressing of at least some of the regions 10 of the patterned electrode 9.

1. A plasmonic coupling device comprising
a first structure, and
a second structure comprising two or more conductive nanoparticles,
wherein each nanoparticle is elongate and is attached to the first structure such that it is oriented with a major axis thereof substantially perpendicular to the first structure.

2. A plasmonic coupling device according to claim 1, in which at least some of the nanoparticles have a width in the region of approximately 2 nm to approximately 500 nm, preferably approximately 10 nm to approximately 100 nm.

3. A plasmonic coupling device according to claim 1, in which at least some of the nanoparticles have a length in the region of approximately 50 nm to approximately 2 μm, preferably approximately 50 nm to approximately 500 nm.

4. A plasmonic coupling device according to claim 1, which comprises one to tens of nanoparticles.

5. A plasmonic coupling device according to claim 1, in which the nanoparticles have a separation in the region of approximately 2 nm to approximately 1500 nm, preferably approximately 20 nm to approximately 1.5 μm.

6. A plasmonic coupling device according to claim 1, in which the nanoparticles comprise at least one one-dimensional pattern of nanoparticles.

7. A plasmonic coupling device according to claim 6 in which the nanoparticles comprise a chain of nanoparticles.

8. A plasmonic coupling device according to claim 1, in which the nanoparticles comprise at least one two-dimensional pattern of nanoparticles.

9. A plasmonic coupling device according to claim 8, in which the nanoparticles comprise at least one quasi-periodic, hexagonal, two-dimensional pattern of nanoparticles.

10. A plasmonic coupling device according to claim 8, which comprises an electrode, patterned to address one or more nanoparticles.

11. A plasmonic coupling device according to claim 8, in which the second structure comprises two or more assemblies each comprising one or more conductive nanoparticles.

12. A plasmonic coupling device according to claim 11, in which at least some of the assemblies of one or more nanoparticles comprise one to tens of nanoparticles.

13. A plasmonic coupling device according to claim 11, in which at least some of the assemblies comprise a plurality of nanoparticles which have a nanoparticle to nanoparticle separation in the region of approximately 2 nm to approximately 1500 nm, preferably approximately 20 nm to approximately 500 nm.

14. A plasmonic coupling device according to claim 13, in which at least some of the assemblies of a plurality of nanoparticles comprise at least one quasi-periodic, hexagonal, two-dimensional pattern of nanoparticles.

15. A plasmonic coupling device according to claim 11, which comprises a plurality of assemblies of one or more nanoparticles, at least some of which assemblies have a separation in the region of approximately 50 nm to approximately 1.5 μm.

16. A plasmonic coupling device according to claim 11, which comprises a one-dimensional arrangement of assemblies of one or more nanoparticles which comprises a chain of assemblies of one or more nanoparticles, having a period in the region of approximately 50 nm to approximately 1.5 μm.

17. A plasmonic coupling device according to claim 11, which comprises an electrode, which is patterned to address one or more of the assemblies of one or more nanoparticles.

18. A plasmonic coupling device according to claim 1, in which the second structure comprises insulator material which contains a plurality of pores, at least some of the pores are oriented with a major axis thereof substantially perpendicular to the first structure, and at least some of the nanoparticles of the device are contained in the pores.

19. A plasmonic coupling device according to claim 18, in which the at least some of the nanoparticles are contained in the pores, with a space between at least a part of each nanoparticle and at least a part of each pore, and at least some of the spaces are at least partially filled with at least one substance.

20. A plasmonic coupling device according to claim 1, in which the first structure has a thickness in the region of approximately 10 nm to approximately 1000 nm.

21. A plasmonic coupling device according to claim 1, in which the plasmonic coupling device has a thickness in the region of approximately 50 nm to approximately 2000 nm.

22. A method of manufacturing a plasmonic coupling device, comprising the steps of:
forming a first structure, and
forming a second structure comprising two or more conductive nanoparticles, by
forming insulator material comprising two or more pores on a surface of the first structure, and forming a nanoparticle in at least two of the pores, wherein the or each nanoparticle is elongate and is oriented with a major axis thereof substantially perpendicular to the first structure.

23. A method of manufacturing a plasmonic coupling device, comprising the steps of:
forming a first structure, and
forming a second structure comprising two or more assemblies each comprising one or more conductive nanoparticles, by
forming insulator material comprising two or more assemblies each comprising one or more pores on a surface of the first structure, and forming a nanoparticle in the or at least some of the pores of the two or more assemblies,
wherein the or each nanoparticle is elongate and is oriented with a major axis thereof substantially perpendicular to the first structure.

24. A method of manufacturing a plasmonic coupling device according to claim 22, in which forming the insulator material on the surface of the first structure comprises placing at least one layer of conductive material on the first structure, and treating the layer of conductive material by anodisation to form the insulator material, which treatment also causes formation of the two or more assemblies of one or more pores in the insulator material.

25. A method of manufacturing a plasmonic coupling device according to claim 24, which comprises obtaining a desired arrangement of assemblies of one or more nanoparticles by allowing pores to form in the insulator material in a pattern which is at least partially dictated by one or more characteristics of the layer of conductive material forming the insulator material, and forming nanoparticles in appropriate pores so as to obtain the desired arrangement of assemblies of one or more nanoparticles.

26. A method of manufacturing a plasmonic coupling device according to claim 24, which comprises obtaining a desired arrangement of assemblies of one or more nanoparticles by providing the plasmonic coupling device with an electrode which is patterned to allow growth of nanoparticles, using the patterned electrode to form arrays of assemblies of nanoparticles, and using the patterned electrode to address the desired arrangement of assemblies.

27. A method of manufacturing a plasmonic coupling device according to claim 24, comprising obtaining a desired arrangement of assemblies of one or more nanoparticles by processing the layer of conductive material prior to treatment thereof to form the insulator material, to form an arrangement of assemblies of one or more pores, and forming nanoparticles in the pores to obtain the desired arrangement of assemblies of one or more nanoparticles.

28. A method of manufacturing a plasmonic coupling device according to claim 24, comprising obtaining a desired arrangement of assemblies of one or more nanoparticles by processing the layer of conductive material prior to treatment thereof to form the insulator material, to form an arrangement of assemblies of one or more pores, and forming nanoparticles in appropriate pores to obtain the desired arrangement of assemblies of one or more nanoparticles.

29. A method of manufacturing a plasmonic coupling device according to claim 22, comprising removing material from at least some of the pores containing a nanoparticle to provide a space between the insulator material and the nanoparticle, by etching insulator material surrounding a pore, by channelling an etching substance along the nanoparticle contained in the pore and etching outwards from the nanoparticle.

30. A waveguide comprising one or more plasmonic coupling devices according to claim 1.

31. A waveguide according to claim 30, in which the throughput spectrum of the waveguide is controllable, by tuning one or more properties of at least some of the nanoparticles.

32. A plasmonic sensor comprising one or more plasmonic coupling devices according to claim 1.

33. A transistor comprising one or more plasmonic coupling devices according to claim 1.

34. A transistor according to claim 33, in which at least some of the plasmonic coupling devices of the transistor comprise a dielectric insulator material, which comprises an active plasmonic material capable of exhibiting a nonlinear response to excitation.

35. A transistor according to claim 34, which operates by using near-field interactions of the assemblies of one or more nanoparticles of at least some of the plasmonic coupling devices, to excite the dielectric insulator material, to produce a nonlinear response which modulates transmittance of the or each device.

36. A transistor according to claim 35, in which the dielectric insulator material exhibits a nonlinear response to excitation affecting the refractive index of the material, and the refractive index of the material is controlled by illumination with a signal, allowing control of the transmittance of the transistor.

37. A laser comprising one or more plasmonic coupling devices according to claim 1.

38. A laser according to claim 37, in which at least some of the plasmonic coupling devices of the laser comprise an insulator material, which comprises a material capable of optical gain/optical stimulation.

39. A laser according to claim 38, which operates by using the plasmonic modes excited in the interacting assemblies of one or more nanoparticles of at least some of the plasmonic coupling devices, to stimulate the insulator material of the devices and generate stimulated emission from the or each device.

40. A laser according to claim 37, in which at least some of the plasmonic coupling devices of the laser comprise hollow nanoparticles, at least some of the hollow nanoparticles are at least partially filled with at least one substance which is capable of optical stimulation, and the or each or some of the hollow nanoparticles then provide a lasing cavity.

41. A laser according to claim 40, in which the or each or some of the lasing cavities are spectrally tuned by providing a substance in a space between a hollow nanoparticle and a pore of insulator material containing the nanoparticle.
